(19) United States
(12) Patent Application Publication
(10) Pub. No.: US 2024/0096979 A1
(43) Pub. Date: Mar. 21, 2024

(54) SEMICONDUCTOR STRUCTURE AND METHOD OF FORMING THE SAME

(71) Applicant: Taiwan Semiconductor Manufacturing Company, Ltd., Hsinchu (TW)

(72) Inventor: Wang-Chun HUANG, Kaohsiung City (TW)

(21) Appl. No.: 18/152,938

(22) Filed: Jan. 11, 2023

Related U.S. Application Data
(60) Provisional application No. 63/375,579, filed on Sep. 14, 2022.

(51) Int. Cl. H01L 29/417; H01L 21/02; H01L 21/28; H01L 21/285; H01L 29/06; H01L 29/08; H01L 29/40; H01L 29/423; H01L 29/49; H01L 29/66; H01L 29/775

(52) U.S. Cl. CPC H01L 29/41733; H01L 21/02532; H01L 21/0262; H01L 21/02658; H01L 21/28123; H01L 21/28518; H01L 29/0673; H01L 29/0847; H01L 29/401; H01L 29/42392; H01L 29/4991; H01L 29/66439; H01L 29/775

(57) ABSTRACT

A method for forming a semiconductor structure is provided. The method includes forming a fin structure protruding from a substrate. The fin structure includes alternately stacked first semiconductor material layers and second semiconductor material layers. The method includes forming a spacer layer over the fin structure. The method includes forming a first inter-layer dielectric (ILD) layer over the spacer layer. The method also includes recessing the fin structure and the first ILD layer to form a first opening through the first ILD layer. The method further includes forming an epitaxial structure in the first opening, and forming a second ILD layer over the epitaxial structure and the first ILD layer. In addition, the method includes removing the first semiconductor material layers, and forming a gate structure around the second semiconductor material layers.

### CROSS REFERENCE TO RELATED APPLICATIONS

This application claims the benefit of U.S. Provisional Application No. 63/375,579 filed Sep. 14, 2022, the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes and their structure allows them to be aggressively scaled-down while maintaining gate control and mitigating SCEs. However, integration of fabrication of the GAA features can be challenging.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIGS. 2A to 2I illustrate perspective views of intermediate stages of manufacturing the semiconductor structure along line A-A shown in FIG. 1E in accordance with some embodiments.

FIGS. 3A to 3G illustrate perspective views of intermediate stages of manufacturing the semiconductor structure along line B-B shown in FIG. 1E in accordance with some embodiments.

FIG. 4 illustrates a layout view of the semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third” and the like, may be used herein for ease of description to describe similar or different element(s) or feature(s) as illustrated in the figures, and may be used interchangeably depending on the order of the presence or the contexts of the description.

The nanostructure transistors (e.g. nanosheet transistors, nanowire transistors, multi-bridge channel transistors, nano-ribbon FET, and gate all around (GAA) transistors) described below may be patterned by any suitable method.

Embodiments of semiconductor structures and methods for forming the same are provided. The method for forming the semiconductor structure may include forming an inter-layer dielectric (ILD) layer before forming an epitaxial structure over the fin structure. Accordingly, the lateral width of the epitaxial structure may be confined along the direction in which the gate structure extends. Therefore, the parasitic capacitance between the epitaxial structure and the gate structure may be reduced. As a result, the performance of the resulting semiconductor structure may be improved.

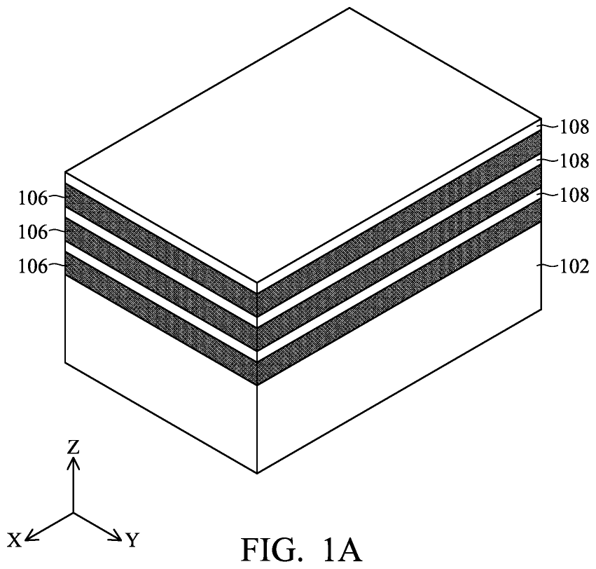

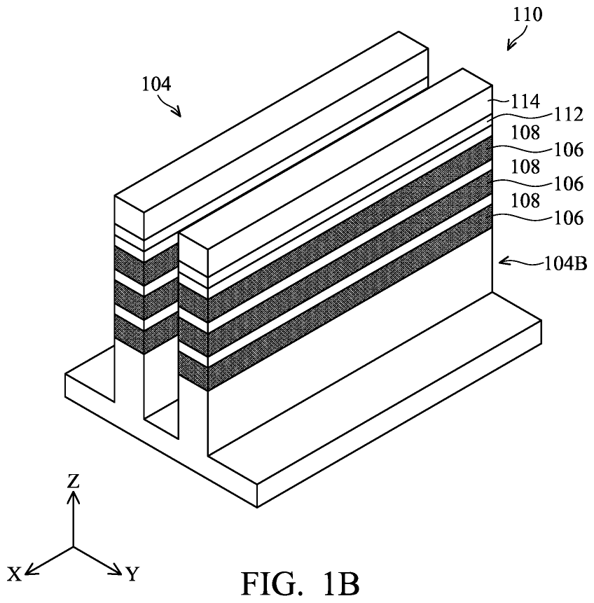

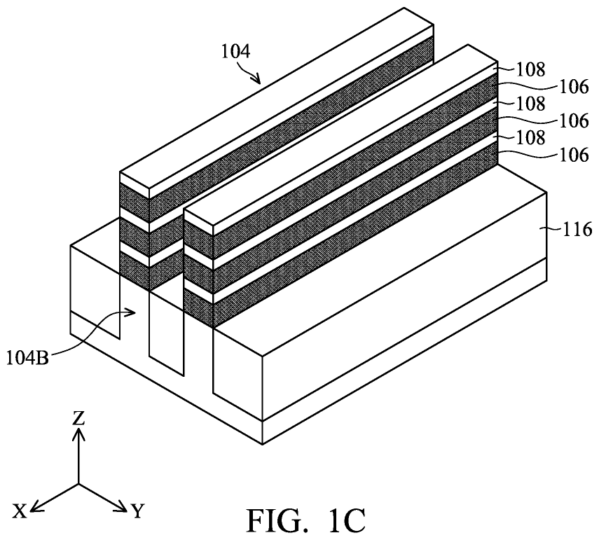

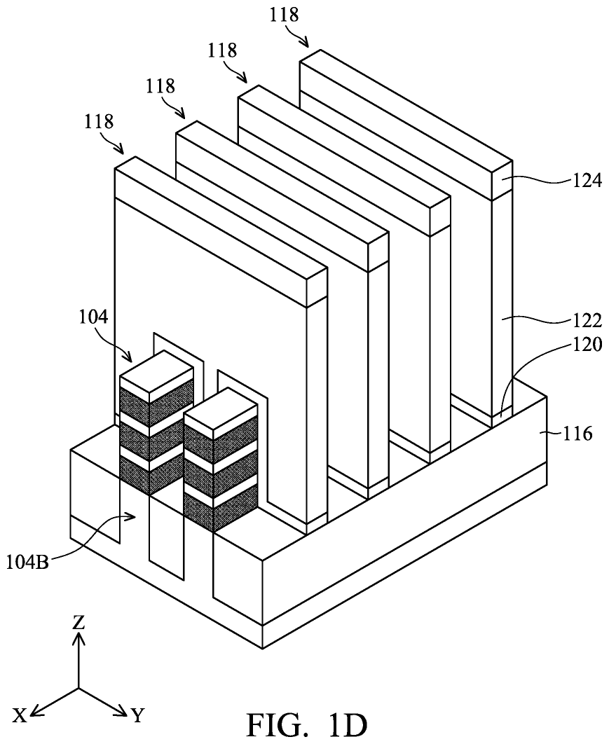

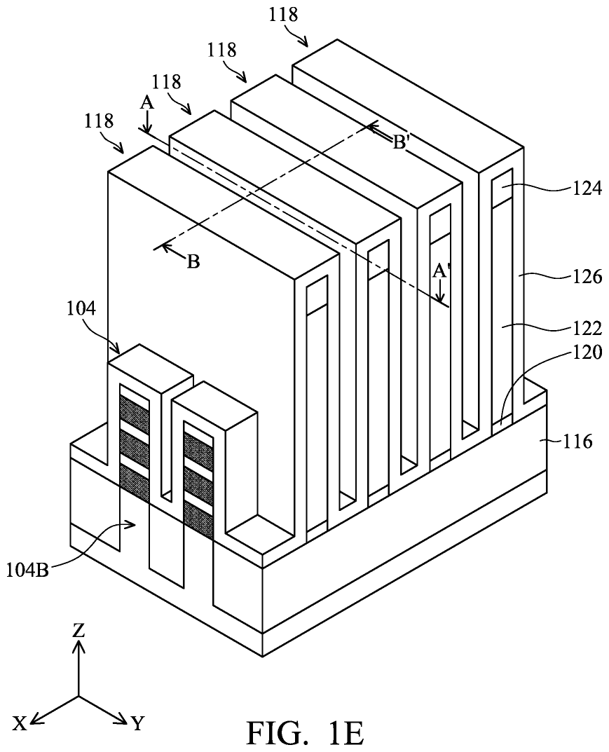

FIGS. 1A to 1E illustrate perspective views of intermediate stages of manufacturing a semiconductor structure in accordance with some embodiments. As shown in FIG. 1A, first semiconductor material layers 106 and second semiconductor material layers 108 are formed over a substrate 102 in accordance with some embodiments. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked to form a semiconductor material stack over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. However, the present disclosure is not limited thereto. In some other embodiments, the first semiconductor material layers 106 are made of silicon, and the second semiconductor material layers 108 are made of SiGe. It should be noted that although three first semiconductor material layers 106 and three second semiconductor material layers 108 are formed, the semiconductor structure may include more or less numbers of the first semiconductor material layers 106 and the second semiconductor material layers 108. For example, the semiconductor structure may include two to five of the first semiconductor material layers 106 and the second semiconductor material layers individually.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the semiconductor material stack are formed over the substrate 102, the semiconductor material stack is patterned to form a plurality of fin structures 104 (e.g. extending along the X direction), as shown in FIG. 1B in accordance with some embodiments. It should be noted that although two fin structures 104 are shown, the semiconductor structure may include more fin structures 104, and the number of the fin structures 104 is not limited thereto. In some embodiments, each of the fin structures 104 includes a base fin structure 104B and the semiconductor material stack of the first semiconductor material layers 106 and the second semiconductor material layers 108. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or CVD, and the nitride layer 114 may be made of silicon nitride, which is formed by CVD, such as LPCVD or plasma-enhanced CVD (PECVD).

After the fin structures 104 are formed, an isolation structure 116 is formed around the fin structures 104, and the mask structure 110 is removed, as shown in FIG. 1C in accordance with some embodiments. The isolation structure 116 is configured to electrically isolate active regions (e.g. the fin structures 104) of the semiconductor structure and is also referred to as shallow trench isolation (STI) feature in accordance with some embodiments.

The isolation structure 116 may be formed by depositing an insulating layer over the substrate 102, planarizing the insulating layer and recessing the planarized insulating layer so that the fin structures 104 are protruded from the isolation structure 116. In some embodiments, the isolation structure 116 is made of silicon oxide, silicon nitride, silicon oxynitride (SiON), another suitable insulating material, or a combination thereof. A single or multiple dielectric liner layers (not shown) may be formed before the isolation structure 116 is formed. In some embodiments, a dielectric liner is made of silicon nitride and the isolation structure formed over the dielectric liner is made of silicon oxide.

After the isolation structure 116 is formed, dummy gate structures 118 are formed across the fin structures 104 and extend over the isolation structure 116 (i.e. along the Y direction), as shown in FIG. 1D in accordance with some embodiments. The dummy gate structures 118 may be used to define the source/drain regions and the channel regions of the resulting semiconductor structure.

In some embodiments, each of the dummy gate structures 118 includes a dummy gate dielectric layer 120 and a dummy gate electrode layer 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, CVD, ALD, physical vapor deposition (PVD), another suitable method, or a combination thereof.

In some embodiments, the dummy gate electrode layers 122 are made of a conductive material. In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using CVD, PVD, or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material, such as polysilicon, may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

After the dummy gate structures 118 are formed, a spacer layer 126 is conformally deposited over the top and sidewall surfaces of the dummy gate structures 118 and the fin structure 104 and over the top surfaces of the isolation structure 116, as shown in FIG. 1E in accordance with some embodiments. In some embodiments, the spacer layer 126 is made of a dielectric material selected from silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some other embodiments, the spacer layer 126 include a multi-layered structure. The sub-layers of the spacer layer 126 are made of different dielectric materials.

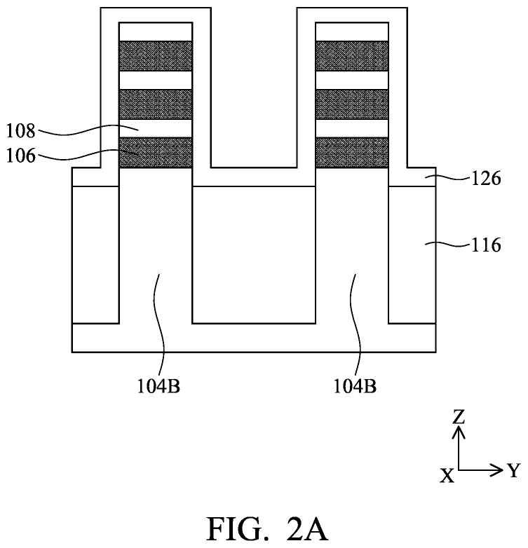

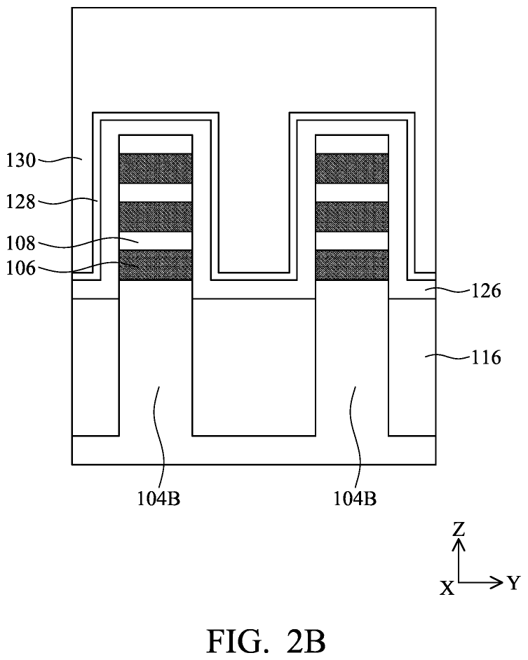

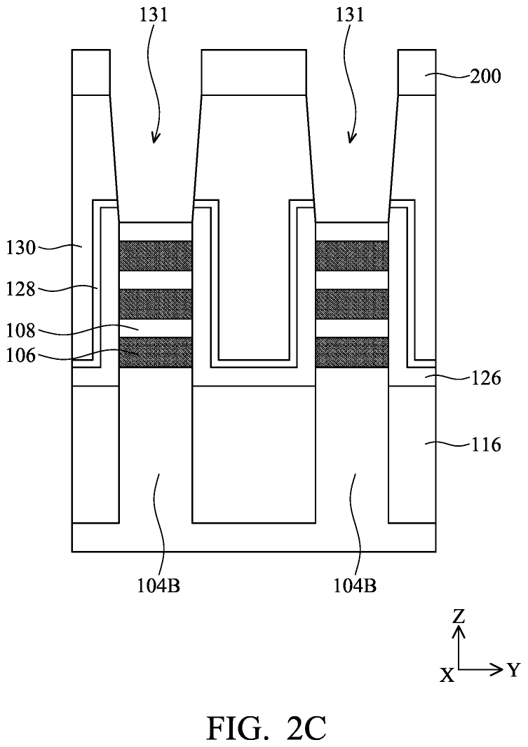

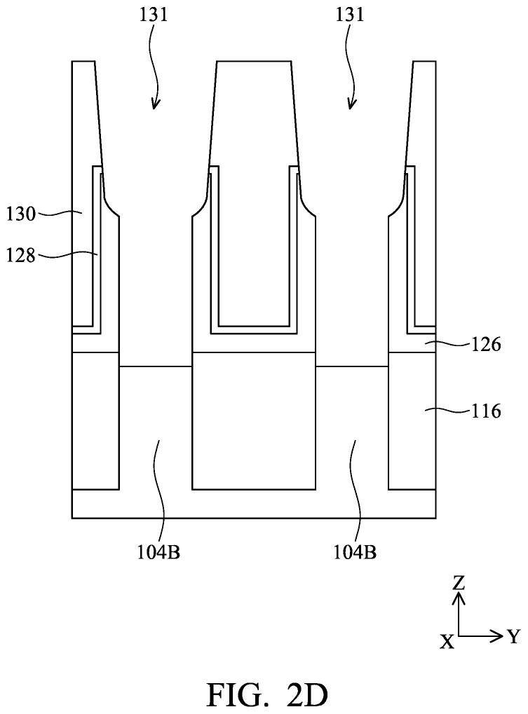

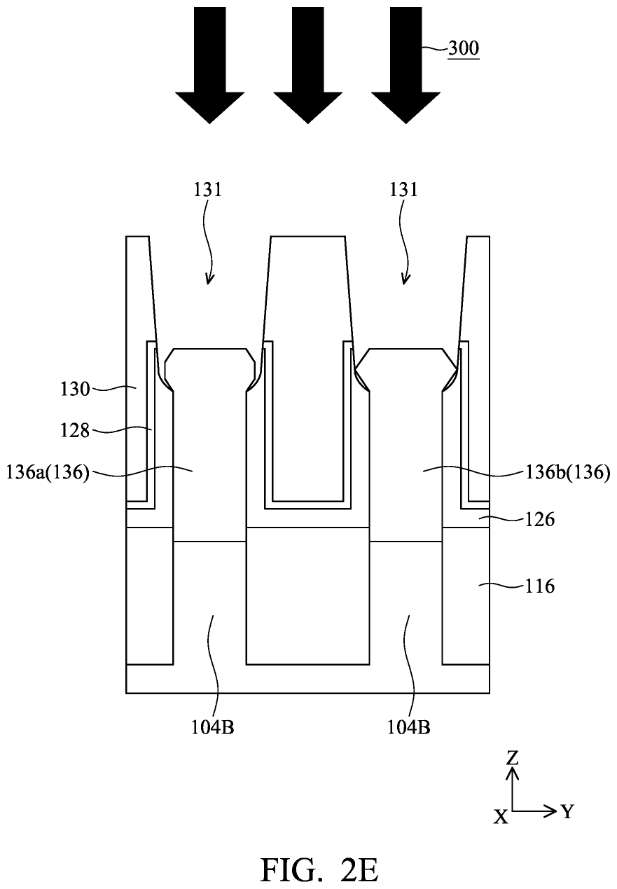

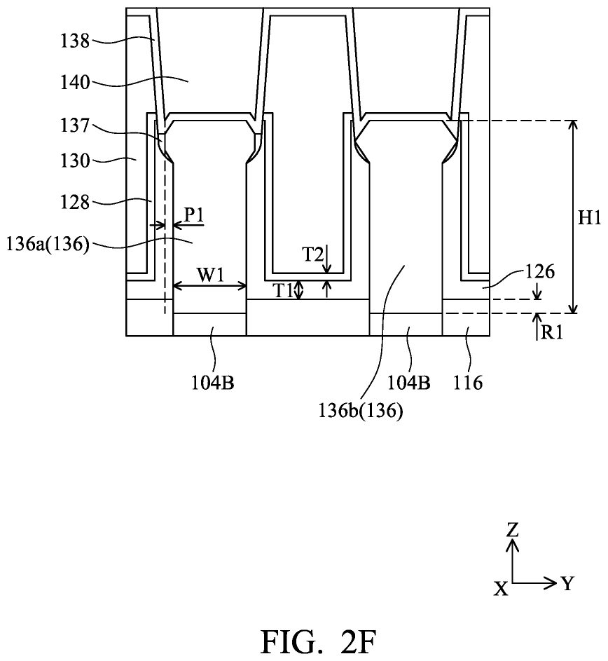

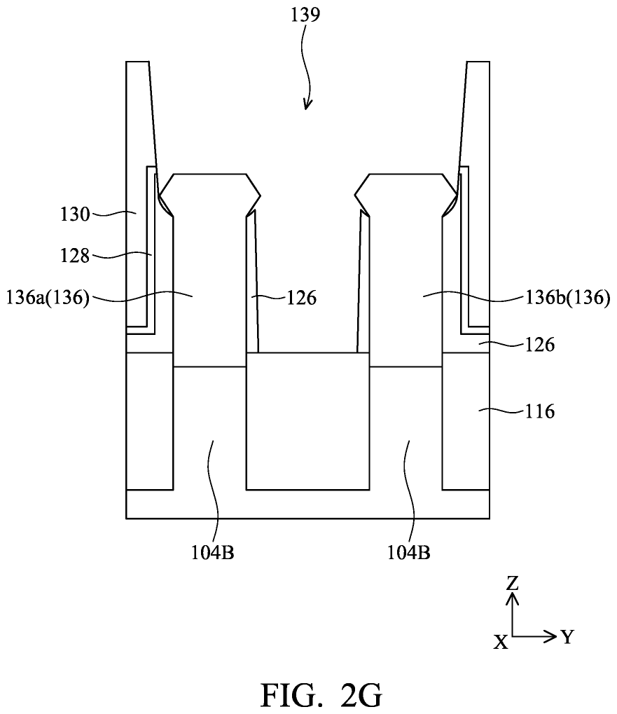

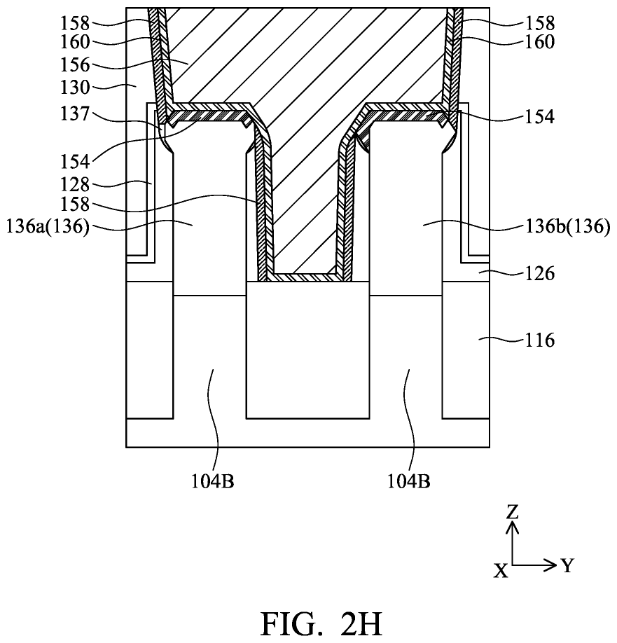

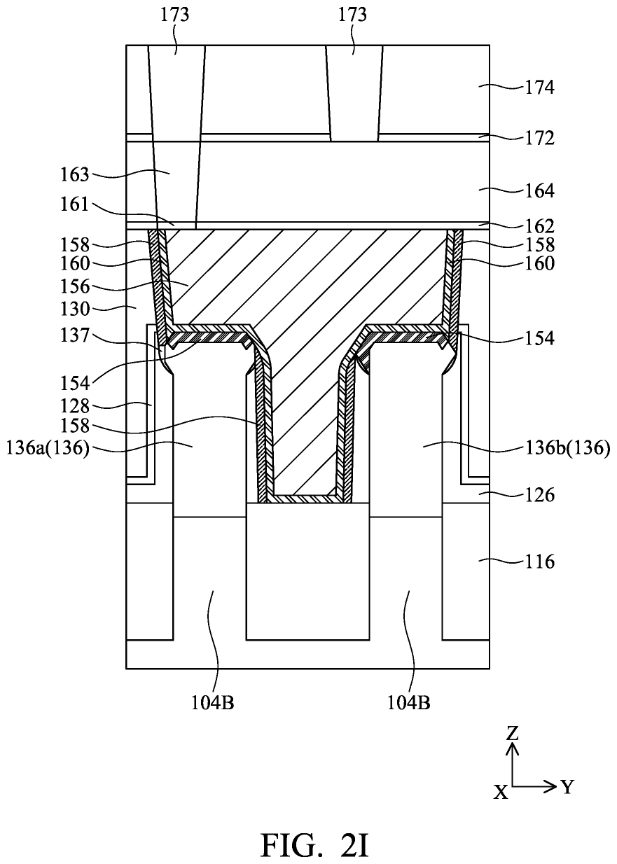

FIGS. 2A to 2I illustrate cross-sectional representations of various stages of manufacturing the semiconductor structure shown along line A-A′ in FIG. 1E in accordance with some embodiments. More specifically, FIG. 2A illustrates the cross-sectional representation shown along line A-A′ in FIG. 1E, and FIGS. 2B to 2I illustrate the processes afterwards in accordance with some embodiments.

After the spacer layer 126 is formed, the spacer layer 126 covers sidewalls of the stacked first semiconductor material layers 106 and the second semiconductor material layers 108, as shown in FIG. 2A in accordance with some embodiments. In some embodiments, the spacer layer 126 covers a portion of the sidewall of the base fin structure 104B. In some embodiments, the spacer layer 126 covers the top surface of the topmost second semiconductor material layer 108.

Next, a first contact etch stop layer 128 is formed over the spacer layer 126, as shown in FIG. 2B in accordance with some embodiments. In some embodiments, the first contact etch stop layer 128 is conformally formed over the spacer layer 126. In some embodiments, the first contact etch stop layer 128 is in contact with the spacer layer 126. After forming the first contact etch stop layer 128, a first inter-layer dielectric (ILD) layer 130 is formed over the first contact etch stop layer 128. In some embodiments, the first contact etch stop layer 128 is made of silicon nitride, silicon oxynitride, and/or other applicable materials. Moreover, the first contact etch stop layer 128 may be formed by plasma enhanced CVD, low-pressure CVD, atomic layer deposition (ALD), or other applicable processes.

In some embodiments, the first ILD layer 130 includes multilayers made of multiple dielectric materials, such as silicon oxide, silicon nitride, silicon oxynitride, phosphosilicate glass (PSG), borophosphosilicate glass (BPSG), low-k dielectric material, and/or other applicable dielectric materials. Examples of the low-k dielectric materials include, but are not limited to, fluorinated silica glass (FSG), carbon doped silicon oxide, amorphous fluorinated carbon, parylene, bis-benzocyclobutenes (BCB), or polyimide. In addition, the first ILD layer 130 may be formed by chemical vapor deposition (CVD), physical vapor deposition, (PVD), atomic layer deposition (ALD), spin-on coating, or another applicable process.

In some embodiments, a planarizing process is performed on the first ILD layer 130 until the top surfaces of the dummy gate structures 118 (for example, referring to FIG. 1E) are exposed. After the planarizing process, the top surfaces of the dummy gate structures 118 may be substantially level with the top surfaces of the spacer layer 126 and the first ILD layer 130. In some embodiments, the planarizing process includes a grinding process, a chemical mechanical polishing (CMP) process, an etching process, another applicable process, or a combination thereof.

Then, a mask layer 200 is formed on the first ILD layer 130, as shown in FIG. 2C in accordance with some embodiments. In some embodiments, the mask layer 200 is formed by deposition processes, which may include a chemical vapor deposition (CVD) process, a high-density plasma chemical vapor deposition (HDPCVD) process, a spin-on process, a sputtering process, or another applicable process. In some embodiments, the mask layer 200 is provided for a subsequent etching process. For example, an etching process is performed to obtain a plurality of first openings 131. In some embodiments, the first openings 131 pass through the first ILD layer 130, the first contact etch stop layer 128, and the spacer layer 126, exposing the top surface of the topmost second semiconductor material layer 108. For example, the etching process may be a dry etching process or a wet etching process. In some embodiments, the etching process is an anisotropic etching process.

After the etching process is complete, multiple stacks of the first semiconductor material layers 106 and second semiconductor material layers 108 are each exposed in the corresponding first openings 131, and these stacks of the first semiconductor material layers 106 and second semiconductor material layers 108 are removed using another etching process via the first openings 131, as shown in FIG. 2D in accordance with some embodiments. In some embodiments, the first openings 131 are widened after the stacks of the first semiconductor material layers 106 and second semiconductor material layers 108 are removed. To be more specific, the first ILD layer 130 and the first contact etch stop layer 128 are partially removed in a lateral manner. In some embodiments, the spacer layer 126 is also laterally removed, and the inner surface of the spacer layer 126 may have a substantially curved profile. In some embodiments, the first openings 131 are deepened since the base fin structures 104B are recessed. In some embodiments, the top surface of the base fin structures 104B is substantially lower than the top surface of the isolation structure 116. However, the present disclosure is not limited thereto. In some other embodiments, the top surface of the base fin structures 104B is substantially level with the top surface of the isolation structure 116.

Afterwards, epitaxial structures 136a and 136b are formed over the base fin structures 104B, as shown in FIG. 2E in accordance with some embodiments. For the sake of simplicity, the epitaxial structures 136a and 136b may be collectively referred to as the epitaxial structures 136. In some embodiments, the epitaxial structures 136 contact and are separated by the spacer layer 126. In some embodiments, the epitaxial structures 136 are formed using an epitaxial growth process, such as MBE, MOCVD, VPE, other applicable epitaxial growth process, or a combination thereof. In some embodiments, the epitaxial structures 136 are made of any applicable material, such as Ge, Si, GaAs, AlGaAs, SiGe, GaAsP, SiP, SiC, SiCP, or a combination thereof. In some embodiments, the epitaxial structures 136 include different types of epitaxial structures. That is, the type of the epitaxial structure 136a is different from the type of the epitaxial structure 136b.

In some embodiments, the epitaxial structures 136 are in-situ doped during the epitaxial growth process. For example, the epitaxial structures 136 may be the epitaxially grown SiGe doped with boron (B). For example, the epitaxial structures 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the epitaxial structures 136 are doped in one or more implantation processes after the epitaxial growth process. Source/drain features may refer to a source or a drain, individually or collectively dependent upon the context.

It is noted that since the spacer layer 126, the first contact etch stop layer 128, and the first ILD layer 130 have defined the first openings 131 for the epitaxial structures 136. The shape (for example, the cross-section) of the epitaxial structures 136 may be controlled. For example, the epitaxial structures 136 are formed along the inner surface of the spacer layer 126 (i.e. the edge of the first opening 131). Accordingly, the epitaxial structures 136 are each formed in a region encircled by the spacer layer 126. To be more specific, each of the epitaxial structures 136 would not laterally extend beyond the outer surface of the spacer layer 126, which is opposite to the inner surface of the spacer layer 126. In some embodiments, the epitaxial structures 136 are formed lower than the top surface of the first contact etch stop layer 128.

Optionally, a gas treatment 300 may be performed prior to forming the epitaxial structures 136. In some embodiments, the gas treatment 300 comprises introducing a gas into the first openings 131. The gas may be Si(CH₃)₄, for example, or any other suitable gaseous material. The gas treatment 300 is configured to enhance the formation of the epitaxial structures 136. Since the first openings 131 have a relatively high depth-width ratio, defects (for example, voids) may occur during the epitaxial growth process. The gas treatment 300 helps to reduce defects during the formation of the epitaxial structures 136.

After the epitaxial structures 136 are formed, a second contact etch stop layer (CESL) 138 is formed over the substrate 102, and then a second inter-layer dielectric (ILD) layer 140 is formed over the second contact etch stop layer 138, as shown in FIG. 2F in accordance with some embodiments. More specifically, the second contact etch stop layer 138 is formed over the epitaxial structures 136 and the first ILD layer 130. In some embodiments, the second contact etch stop layer 138 is made of silicon nitride, silicon oxynitride, and/or other applicable materials. Moreover, the second contact etch stop layer 138 may be formed by plasma enhanced CVD, low-pressure CVD, atomic layer deposition (ALD), or other applicable processes. In some embodiments, the first contact etch stop layer 128 and the second contact etch stop layer 138 are made of the same material using the same method.

In some embodiments, the second ILD layer 140 includes multilayers made of multiple dielectric materials, such as silicon oxide, silicon nitride, silicon oxynitride, phosphosilicate glass (PSG), borophosphosilicate glass (BPSG), low-k dielectric material, and/or other applicable dielectric materials. Examples of the low-k dielectric materials include, but are not limited to, fluorinated silica glass (FSG), carbon doped silicon oxide, amorphous fluorinated carbon, parylene, bis-benzocyclobutenes (BCB), or polyimide. In addition, the second ILD layer 140 may be formed by chemical vapor deposition (CVD), physical vapor deposition, (PVD), atomic layer deposition (ALD), spin-on coating, or another applicable process. In some embodiments, the first ILD layer 130 and the second ILD layer 140 are made of the same material using the same method.

In some embodiments, an air spacer 137 is formed between the epitaxial structures 136 and the spacer layer 126. The second contact etch stop layer 138 covers the air spacer 137. In some embodiments, the width W1 of the base fin structures 104B is about 8 nm to about 60 nm. The width W1 is also the shortest distance from the opposite spacer layer 126. In some embodiments, the sidewall of the epitaxial structure 136 protrudes from the sidewall of the base fin structure 104B, and the length P1 of the protrusion is greater than 0 and less than about 10 nm. For example, the length P1 is measured from the sidewall of the base fin structure 104B to the outermost point of the epitaxial structure 136 located over the base fin structure 104B in the Y direction. However, the present disclosure is not limited thereto. In some other embodiments, the epitaxial structure 136 does not protrude from the sidewall of the base fin structure 104B.

In some embodiments, the height difference R1 between the bottom surface of the epitaxial structures 136 and the top surface of the isolation structure 116 is greater than 0 and less than about 20 nm. However, the present disclosure is not limited thereto. In some other embodiments, the bottom surface of the epitaxial structures 136 may be substantially level with the top surface of the isolation structure 116. In some embodiments, the epitaxial structure having a height H1 of about 30 nm to about 70 nm. In some embodiments, the thickness T1 of the spacer layer 126 is about 5 nm to about 10 nm. In some embodiments, the thickness T2 of the first contact etch stop layer 128 is about 2 nm to about 6 nm. In some embodiments, the thickness T1 of the spacer layer 126 is not less than the thickness T2 of the first contact etch stop layer 128.

In some embodiments, a second opening 139 is formed for a contact 156 that is subsequently formed, as shown in FIG. 2G in accordance with some embodiments. For example, the second ILD layer 140 is etched through, exposing the top surfaces of the epitaxial structures 136 in the second opening 139. In some embodiments, the etching process for forming the second opening 139 may include a dry etching process or a wet etching process. In some embodiments, the second opening 139 extends between the epitaxial structures 136 and exposes a portion of the top surface of the isolation structure 116.

Next, a contact spacer 158 is formed along the sidewalls of the second opening 139, as shown in FIG. 2H in accordance with some embodiments. In some embodiments, the contact spacer 158 is in direct contact with the first ILD layer 130. In some embodiments, the material of the contact spacer 158 includes SiC, LaO, AlO, AlON, ZrO, HfO, SiN, Si, ZnO, ZrN, ZrAlO, TiO, TaO, YO, TaCN, ZrSi, SiOCN, SiOC, SiCN, HfSi, or a combination thereof. In some embodiments, the contact spacer 158 extends onto the top surface of the epitaxial structure 136 along the sidewalls of first ILD layer 130 and the first contact etch stop layer 128.

It should be appreciated that any possible configuration of the contact spacer 158 is within the scope of the present disclosure. In some embodiments, the contact spacer 158 is conformally formed along the sidewalls of first ILD layer 130 and the first contact etch stop layer 128. In some embodiments, the contact spacer 158 vertically overlaps the first contact etch stop layer 128.

Then, a silicide layer 154 is formed on the top of the epitaxial structures 136 in the second opening 139 using a silicidation process, as shown in FIG. 2H in accordance with some embodiments. For example, the silicide layer 154 may be formed in a portion of the epitaxial structures 136. In some embodiments, the silicidation process includes a metal material deposition process and an annealing process performed in sequence. In some embodiments, the deposition process of the silicidation process includes a physical vapor deposition (PVD) process, an atomic layer deposition (ALD) process, or another applicable process. In some embodiments, the annealing process of the silicidation process is performed at a temperature of about 300° C. to about 800° C. After the annealing process, the unreacted metal material is removed. In some embodiments, the silicide layer 154 is conformally formed and therefore the thickness of the silicide layer 154 is substantially uniform across the silicide layer 154.

In some embodiments, the silicide layer 154 is formed of one or more of cobalt silicide (e.g. CoSi, CoSi₂, Co₂Si, Co₂Si, Co₃Si; collectively “Co silicide”), titanium silicide (e.g. Ti₅Si₃, TiSi, TiSi₂, TiSi₃, Ti₆Si₄; collectively “Ti silicide”), nickel silicide (e.g. Ni₃Si, Ni₃₁Si₁₂, Ni₂Si, Ni₃Si₂, NiSi, NiSi₂; collectively “Ni silicide”), copper silicide (e.g. Cu₁₇Si₃, Cu₅₆Si₁₁, Cu₅Si, Cu₃₃Si₇, Cu₄Si, Cu₁₉Si₆, Cu₃Si, Cu₈₇Si₁₃; collectively “Cu silicide”), tungsten silicide (W₅Si₃, WSi₂; collectively “W silicide”), and molybdenum silicide (Mo₃Si, Mo₅Si₃, MoSi₂; collectively “Mo silicide”).

Afterwards, a contact 156 (including barrier layers 160) are filled into the second opening 139 and passes through the first ILD layer 130. In some embodiments, the contact 156 is formed by deposition processes and a subsequent planarization process such as chemical mechanical polish (CMP). The contact 156 may be made of a conductive material, such as tungsten (W), cobalt (Co), ruthenium (Ru), copper (Cu), molybdenum (Mo), any other applicable material, or a combination thereof. In some embodiments, the contact 166 may be formed by any suitable deposition method, such as PVD, CVD, ALD, plating (e.g. electroplating).

In some embodiments, the contact 156 extends lower than the bottom surface of the first contact etch stop layer 128. Accordingly, the contact spacer 158 is sandwiched between the sidewall of the first ILD layer 130 and the sidewall of the contact 156. In some embodiments, the contact 156 is formed over the adjacent two epitaxial structures 136, and is electrically and physically connected to the adjacent two epitaxial structures 136. In some embodiments, the top surface of the contact 156 may be leveled with the top surface of the first ILD layer 130. For example, the contact 156 may be surrounded by the first ILD layer 130. In some embodiments, the contact 156 comes into physical contact with the top surface of the isolation structure 116, which is exposed in the second opening 139.

Next, a contact etch stop layer 162 is formed over the contact 156 and the first ILD layer 130, and a conductive pad 161 is formed in the contact etch stop layer 162 and electrically connected to the contact 156, as shown in FIG. 2I in accordance with some embodiments. For example, the contact etch stop layer 162 includes silicon nitride, silicon oxynitride, and/or other applicable materials. Moreover, the contact etch stop layer 162 may be formed by plasma enhanced CVD, low-pressure CVD, atomic layer deposition (ALD), or other applicable processes. In some embodiments, the contact etch stop layer 162 is made of the same material and/or using the same method as the first contact etch stop layer 128 and the second contact etch stop layer 138. The conductive pad 161 includes a conductive material such as tungsten (W), cobalt (Co), nickel (Ni), copper (Cu), silver (Ag), gold (Au), aluminum (Al), any other suitable conductive material, or a combination thereof. In some embodiments, the conductive pad 161 may be omitted, and a subsequently formed through-via 163 may be formed through the contact etch stop layer 162.

An inter-layer dielectric (ILD) layer 164 is then formed over the contact etch stop layer 162, and a through-via 163 is formed in the ILD layer 164. For example, the ILD layer 164 includes multilayers made of multiple dielectric materials, such as silicon oxide, silicon nitride, silicon oxynitride, phosphosilicate glass (PSG), borophosphosilicate glass (BPSG), low-k dielectric material, and/or other applicable dielectric materials. Examples of the low-k dielectric materials include, but are not limited to, fluorinated silica glass (FSG), carbon doped silicon oxide, amorphous fluorinated carbon, parylene, bis-benzocyclobutenes (BCB), or polyimide. In addition, the ILD layer 164 may be formed by chemical vapor deposition (CVD), physical vapor deposition, (PVD), atomic layer deposition (ALD), spin-on coating, or another applicable process. The through-via 163 includes conductive material such as tungsten (W), cobalt (Co), nickel (Ni), copper (Cu), silver (Ag), gold (Au), aluminum (Al), any other suitable conductive material, or a combination thereof.

Optionally, another contact etch stop layer 172, an inter-layer dielectric (ILD) layer 174, and a metal line 173 are then formed over the ILD layer 164. For example, the contact etch stop layer 172 includes silicon nitride, silicon oxynitride, and/or other applicable materials. Moreover, the contact etch stop layer 172 may be formed by plasma enhanced CVD, low-pressure CVD, atomic layer deposition (ALD), or other applicable processes. In some embodiments, the ILD layer 174 includes multilayers made of multiple dielectric materials, such as silicon oxide, silicon nitride, silicon oxynitride, phosphosilicate glass (PSG), borophosphosilicate glass (BPSG), low-k dielectric material, and/or other applicable dielectric materials. Examples of the low-k dielectric materials include, but are not limited to, fluorinated silica glass (FSG), carbon doped silicon oxide, amorphous fluorinated carbon, parylene, bis-benzocyclobutenes (BCB), or polyimide. In addition, the ILD layer 174 may be formed by chemical vapor deposition (CVD), physical vapor deposition, (PVD), atomic layer deposition (ALD), spin-on coating, or another applicable process. The metal line 173 includes conductive material such as tungsten (W), cobalt (Co), nickel (Ni), copper (Cu), silver (Ag), gold (Au), aluminum (Al), any other suitable conductive material, or a combination thereof. The metal line 173 may be configured for the connection in the X direction, but the present disclosure is not limited thereto.

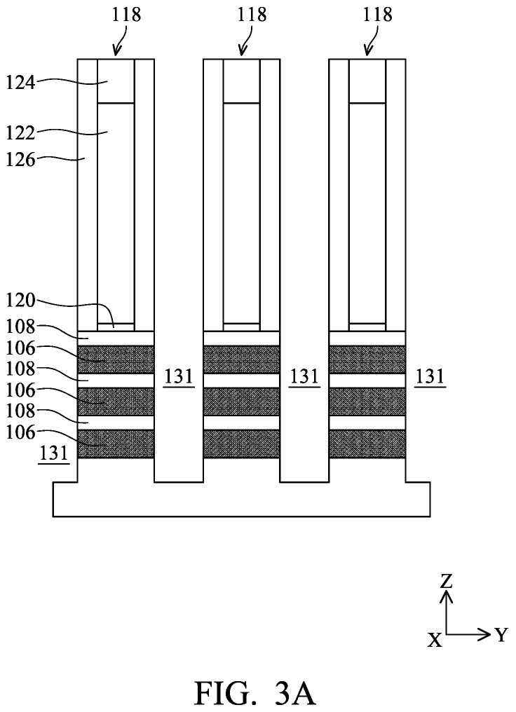

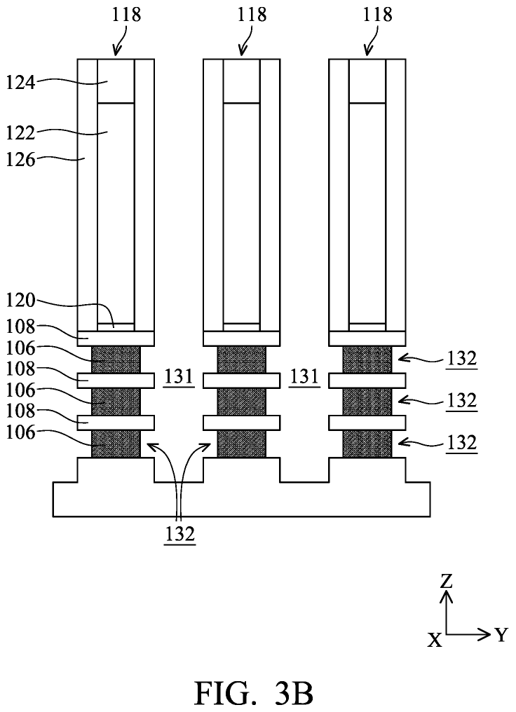

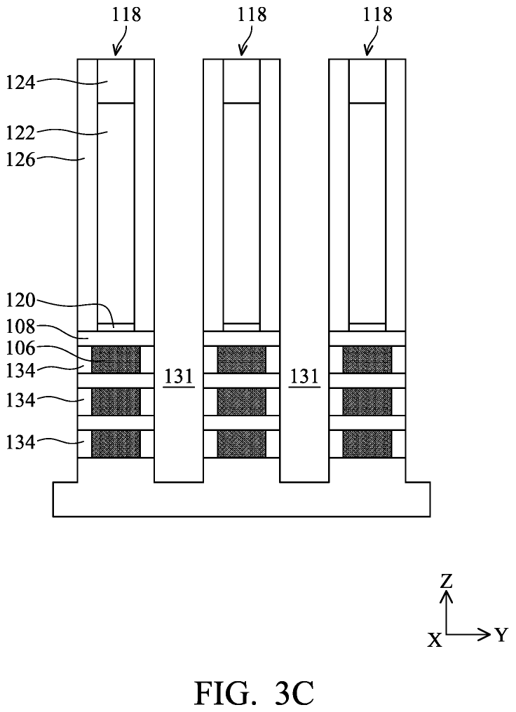

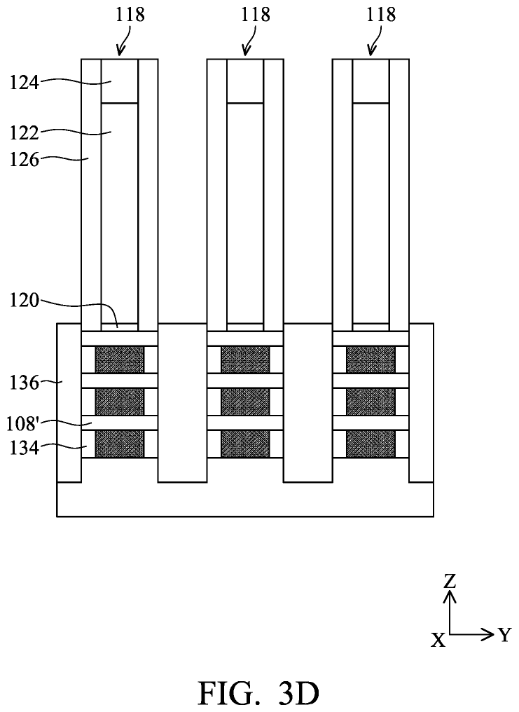

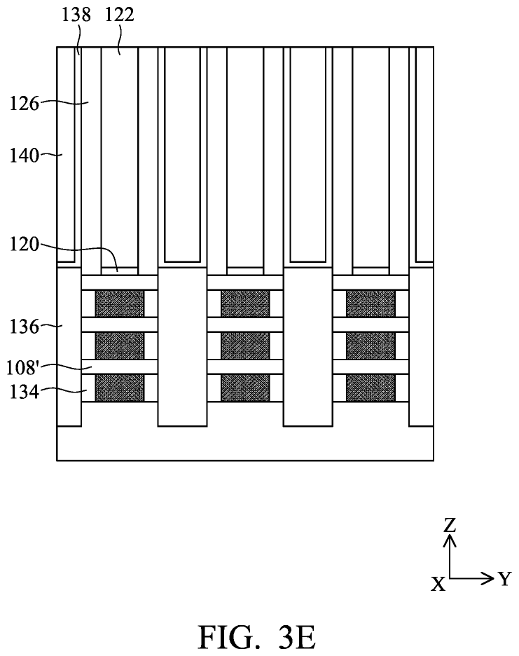

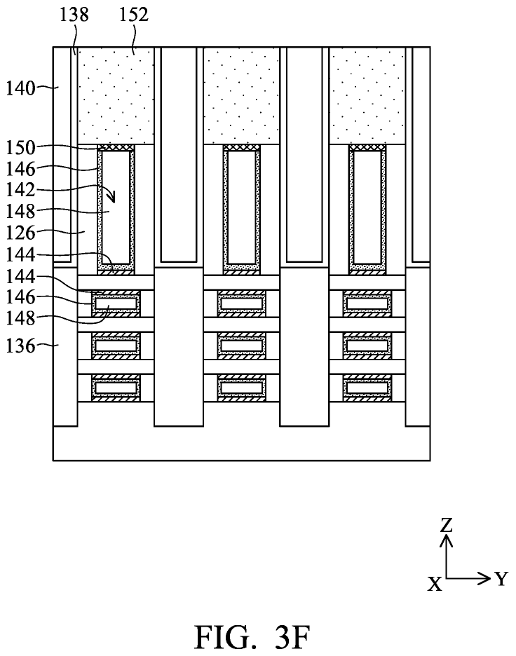

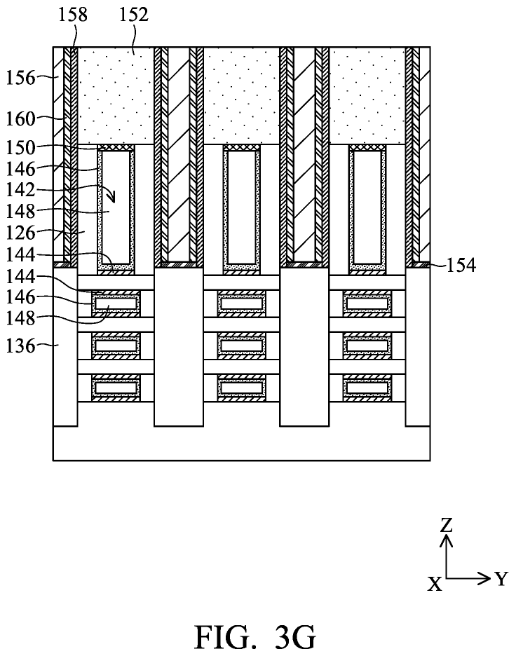

FIGS. 3A to 3G illustrate cross-sectional representations of various stages of manufacturing the semiconductor structure shown along line B-B′ in FIG. 1E in accordance with some embodiments. More specifically, FIG. 3A illustrates the cross-sectional representation shown along line B-B′ in FIG. 1E, and FIGS. 3B to 3G illustrate the processes afterwards in accordance with some embodiments. It should be noted that the process shown in FIG. 3A is at the same step with the process shown in FIG. 2D. For the sake of simplicity in description, the previous processes will not be discussed in detail as follows.

After the spacer layer 126 is formed, the source/drain regions of the fin structures 104 (one of which is shown as an example) are recessed to form a plurality of first openings 131, as shown in FIG. 3A in accordance with some embodiments. More specifically, the first semiconductor material layers 106 and the second semiconductor material layers 108 not covered by the dummy gate structures 118 and the spacer layer 126 are removed in accordance with some embodiments. In some other embodiments, some portions of the base fin structures 104B may also be recessed to form curved top surfaces (not shown).

In some embodiments, the fin structures 104 are recessed by performing an etching process. The etching process may be an anisotropic etching process, such as dry plasma etching, and the dummy gate structure 118 and the spacer layer 126 are used as etching masks during the etching process.

After the first openings 131 are formed, the first semiconductor material layers 106 exposed by the first openings 131 are laterally recessed to form notches 132, as shown in FIG. 3B in accordance with some embodiments.

In some embodiments, an etching process is performed on the semiconductor structure to laterally recess the first semiconductor material layers 106 of the fin structure 104 from the first openings 131. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, inner spacers 134 are formed in the notches 132 between the second semiconductor material layers 108, as shown in FIG. 3C in accordance with some embodiments. The inner spacers 134 are configured to separate the epitaxial structures (for example, source/drain structures) and the gate structures formed in subsequent manufacturing processes in accordance with some embodiments. In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof.

After the inner spacers 134 are formed, epitaxial structures 136 are formed in the first openings 131, as shown in FIG. 3D in accordance with some embodiments. After the epitaxial structures 136 are formed, the second contact etch stop layer (CESL) 138 is conformally formed to cover the epitaxial structures 136 and the second ILD layer 140 is formed over the second contact etch stop layer 138, as shown in FIG. 3E in accordance with some embodiments.

After the second contact etch stop layer 138 and the second inter-layer dielectric layer 140 are deposited, a planarization process such as CMP or an etch-back process may be performed until the gate electrode layers 122 of the dummy gate structures 118 are exposed, as shown in FIG. 3E in accordance with some embodiments.

Next, the dummy gate structures 118 are replaced by gate structure 142, as shown in FIG. 3F in accordance with some embodiments. More specifically, the dummy gate structures 118 and the first semiconductor material layers 106 are removed to form nanostructures 108′ with the second semiconductor material layers 108 in accordance with some embodiments. The removal process may include one or more etching processes. For example, when the dummy gate electrode layers 122 are polysilicon, a wet etchant such as a tetramethylammonium hydroxide (TMAH) solution may be used to selectively remove the dummy gate electrode layers 122. Afterwards, the dummy gate dielectric layers 120 may be removed using a plasma dry etching, a dry chemical etching, and/or a wet etching. The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions. In some embodiments, the upper portion of the spacer layer 126 is also removed.

After the nanostructures 108′ are formed, gate structures 142 are formed in such a way that they wrap around the nanostructures 108′, as shown in FIG. 3F in accordance with some embodiments. The gate structures 142 wrap around the nanostructures 108′ to form gate-all-around transistor structures in accordance with some embodiments. In some embodiments, the gate structure 142 includes an interfacial layer 144, a gate dielectric layer 146, and a gate electrode layer 148.

In some embodiments, the interfacial layers 144 are oxide layers formed around the nanostructures 108′ and on the top of the base fin structure 104B. In some embodiments, the interfacial layers 144 are formed by performing a thermal process. In some embodiments, the gate dielectric layers 146 are formed over the interfacial layers 144, so that the nanostructures 108′ are surrounded (e.g. wrapped) by the gate dielectric layers 146. In addition, the gate dielectric layers 146 also cover the sidewalls of the spacer layer 126 and the inner spacers 134 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 146 are formed using CVD, ALD, another applicable method, or a combination thereof.

In some embodiments, the gate electrode layers 148 are formed on the gate dielectric layer 146. In some embodiments, the gate electrode layers 148 are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layers 148 are formed using CVD, ALD, electroplating, another applicable method, or a combination thereof. Other conductive layers, such as work function metal layers, may also be formed in the gate structures 142, although they are not shown in the figures. After the interfacial layers 144, the gate dielectric layers 146, and the gate electrode layers 148 are formed, a planarization process such as CMP or an etch-back process may be performed until the inter-layer dielectric layer 140 is exposed.

Afterwards, an etch back process is performed to remove the upper portion of the gate structures 142, and cap layers 150 and mask layers 152 are formed over the gate structures 142, as shown in FIG. 3F in accordance with some embodiments. More specifically, the upper portion of the gate structures 142 are removed to form a recess in the inter-layer dielectric layer 140 and the cap layers 150 and the mask layers 152 are formed in the recess in accordance with some embodiments.

In some embodiments, the cap layers 150 are made of W, Ti, Co, Ru, Ni, or the like. The cap layers 150 may be formed using CVD, ALD, electroplating, another applicable method, or a combination thereof. In some embodiments, the cap layers 150 are selectively formed over the gate structures 142. In some embodiments, the mask layers 152 are made of SiO₂, Si₃N₄, SiON, SiOCN, SiOCH, or the like. The mask layers 152 may be formed using CVD, ALD, electroplating, another applicable method, or a combination thereof.

After the mask layers 152 are formed, second openings are formed through the second contact etch stop layer 138 and the inter-layer dielectric layer 140, and silicide layers 154 and contacts 156 are formed over the epitaxial structures 136, as shown in FIG. 3G in accordance with some embodiments. In some embodiments, contact spacers 158 and barrier layers 160 are formed around the contacts 156.

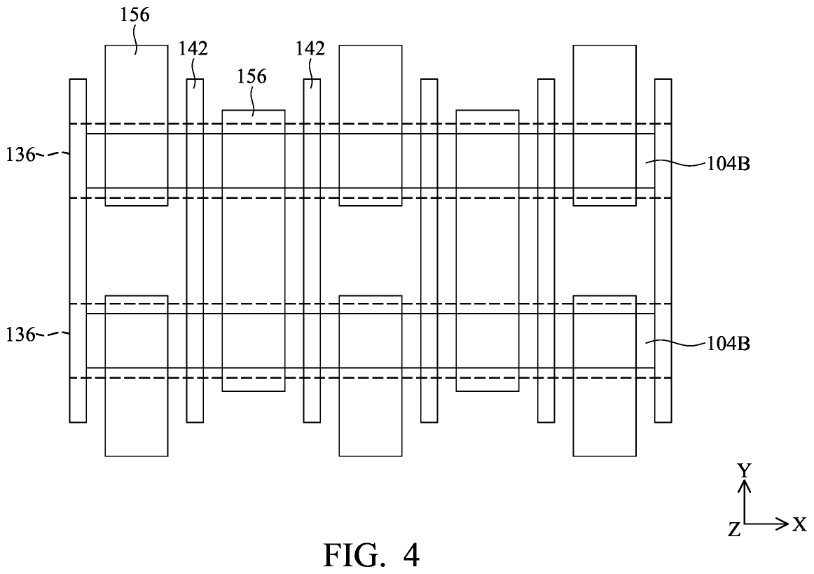

FIG. 4 illustrates a layout view of the semiconductor structure in accordance with some embodiments. It should be noted that the width of the epitaxial structures 136 is confined in the Y direction. That is to say, the epitaxial structures 136 would not protrude too far away from the base fin structures 104B in the Y direction. As a result, the overlapped area between the epitaxial structures 136 and the gate structures 142 may be maintained. That is the epitaxial structures 136 and the gate structures 142 may be kept from being too close, and therefore reducing the parasitic capacitance between the epitaxial structure and the gate structure. As a result, high power efficiency for the semiconductor structure may be achieved, and the performance of the resulting semiconductor structure may be improved.

As set forth above, the present disclosure provides a method for forming a semiconductor. The method includes forming a first ILD layer prior to forming an epitaxial structure over the fin structure. Using the spacer layer and the first ILD layer to confine the lateral profile (for example, the width) of the epitaxial structure. In this way, the overlapped area between the epitaxial structure and the gate structure can be maintained, thereby reducing the parasitic capacitance between the epitaxial structure and the gate structure. As a result, the performance of the resulting semiconductor structure may be improved. In response to the formation of the first ILD layer, a second ILD layer is temporarily formed over the epitaxial structure and will be removed for the subsequently formed contact.

In some embodiments, a method for forming a semiconductor structure is provided, and the method includes forming a fin structure protruding from a substrate. The fin structure includes alternately stacked first semiconductor material layers and second semiconductor material layers. The method includes forming a spacer layer over the fin structure. The method includes forming a first inter-layer dielectric (ILD) layer over the spacer layer. The method also includes recessing the fin structure and the first ILD layer to form a first opening through the first ILD layer. The method further includes forming an epitaxial structure in the first opening, and forming a second ILD layer over the epitaxial structure and the first ILD layer. In addition, the method includes removing the first semiconductor material layers, and forming a gate structure around the second semiconductor material layers.

In some embodiments, a method for forming a semiconductor structure is provided, and the method includes forming a plurality of fin structures protruding from a substrate. Each of the fin structures comprises alternately stacked first semiconductor material layers and second semiconductor material layers. The method includes forming a spacer layer over the fin structures, and forming a contact etch stop layer and an inter-layer dielectric (ILD) layer over the spacer layer. The method includes etching the ILD layer, the contact etch stop layer and the spacer layer to form a plurality of openings through the ILD layer and the contact etch stop layer. The method also includes removing the first semiconductor material layers and second semiconductor material layers exposed in the openings. The method includes forming an epitaxial structure in each of the openings and over each of the fin structures. The method includes removing the first semiconductor material layers, and forming a gate structure around the second semiconductor material layers.

In some embodiments, a semiconductor structure is provided, and the semiconductor structure includes a fin structure over a substrate. The semiconductor structure includes channel layers formed over the substrate. The semiconductor structure includes a gate structure that wraps around the channel layers. The semiconductor structure also includes a spacer layer formed over the substrate. The semiconductor structure includes an epitaxial structure formed over the fin structure and along the inner surface of the spacer layer, wherein the epitaxial structure is formed in a region encircled by the spacer layer. The semiconductor structure further includes a contact etch stop layer and an ILD layer formed on the outer surface of the spacer layer, wherein the outer surface is opposite to the inner surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a fin structure protruding from a substrate, wherein the fin structure comprises first semiconductor material layers and second semiconductor material layers alternately stacked;
forming a spacer layer over the fin structure;
forming a first inter-layer dielectric (ILD) layer over the spacer layer;
recessing the fin structure and the first ILD layer to form a first opening through the first ILD layer;
forming an epitaxial structure in the first opening;
forming a second ILD layer over the epitaxial structure and the first ILD layer;
removing the first semiconductor material layers; and
forming a gate structure around the second semiconductor material layers.

2. The method as claimed in claim 1, further comprising:
forming a second opening through the second ILD layer to expose the epitaxial structure; and
forming a contact in the second opening over the epitaxial structure.

3. The method as claimed in claim 2, further comprising:
forming a contact spacer on a sidewall of the second opening before forming the contact.

4. The method as claimed in claim 3, wherein the contact spacer is in direct contact with the first ILD layer.

5. The method as claimed in claim 1, further comprising:
forming a first contact etch stop layer over the spacer layer before forming the first ILD layer; and
forming a second contact etch stop layer over the over the epitaxial structure before forming the second ILD layer.

6. The method as claimed in claim 5, wherein forming the second contact etch stop layer comprises forming the second contact etch stop layer lower than a top surface of the first contact etch stop layer.

7. The method as claimed in claim 5, wherein recessing the fin structure comprises removing a portion of the first contact etch stop layer and a portion of the spacer layer.

8. The method as claimed in claim 1, wherein forming the epitaxial structure in the opening comprises forming the epitaxial structure having a height of about 30 nm to about 70 nm.

9. The method as claimed in claim 1, further comprising
forming an air spacer between the epitaxial structure and the spacer layer.

10. The method as claimed in claim 1, further comprising:
performing a gas treatment prior to forming the epitaxial structure, wherein the gas treatment comprises introducing a gas into the opening, and the gas comprises Si(CH₃)₄.

11. A method for forming a semiconductor structure, comprising:
forming a plurality of fin structures protruding from a substrate, wherein each of the fin structures comprises first semiconductor material layers and second semiconductor material layers alternately stacked;
forming a spacer layer over the fin structures;
forming a contact etch stop layer and an inter-layer dielectric (ILD) layer over the spacer layer;
etching the ILD layer, the contact etch stop layer and the spacer layer to form a plurality of openings through the ILD layer and the contact etch stop layer;
removing the first semiconductor material layers and second semiconductor material layers exposed in the openings;
forming an epitaxial structure in each of the openings and over each of the fin structures;
removing the first semiconductor material layers; and
forming a gate structure around the second semiconductor material layers.

12. The method as claimed in claim 11, further comprising:
forming an isolation structure between the fin structures, wherein a height difference between a bottom surface of the epitaxial structures and a top surface of the isolation structure is greater than 0 and less than about 20 nm.

13. The method as claimed in claim 11, wherein a thickness of the spacer layer is not less than a thickness of the contact etch stop layer.

14. The method as claimed in claim 11, further comprising:
forming a contact electrically and physically connected to adjacent two of the epitaxial structures.

15. A semiconductor structure, comprising:
a fin structure over a substrate;
channel layers formed over the substrate;
a gate structure wrapping around the channel layers;
a spacer layer formed over the substrate;
an epitaxial structure formed over the fin structure and along an inner surface of the spacer layer, wherein the epitaxial structure is formed in a region encircled by the spacer layer; and
a contact etch stop layer and an ILD layer formed on an outer surface of the spacer layer, wherein the outer surface is opposite to the inner surface.

16. The semiconductor structure as claimed in claim 15, further comprising:
a silicide layer formed on a top of the epitaxial structure; and
a contact over the silicide layer, wherein the contact extends lower than a bottom surface of the contact etch stop layer.

17. The semiconductor structure as claimed in claim 16, further comprising:
a contact spacer sandwiched between a sidewall of the ILD layer and a sidewall of the contact, wherein the contact spacer vertically overlaps the contact etch stop layer.

18. The method as claimed in claim 16, further comprising:
an isolation structure formed around the fin structure, wherein the contact comes into physically contact with a top surface of the isolation structure.

19. The semiconductor structure as claimed in claim 15, wherein a sidewall of the epitaxial structure protrudes from a sidewall of the fin structure, and the protrusion is greater than 0 and less than about 10 nm.

20. The semiconductor structure as claimed in claim 15, further comprising:
an air spacer formed between the epitaxial structure and the spacer layer.
